(19) United States
(12) Patent Application Publication
(10) Pub. No.: US 2009/0008662 A1
(43) Pub. Date: Jan. 8, 2009

(54) LIGHTING DEVICE PACKAGE

(76) Inventors: Ian Ashdown, West Vancouver (CA); Shane Harrah, Everett, WA (US)

Correspondence Address: PHILIPS INTELLECTUAL PROPERTY & STANDARDS, 3 BURLINGTON WOODS DRIVE, BURLINGTON, MA, 01803, US

(21) Appl. No.: 11/773,473

(22) Filed: Jul. 5, 2007

(51) Int. Cl. H01L 33/00

(52) U.S. Cl. 257/98; 257/E33.059

(57) ABSTRACT

The invention provides a lighting device package with one or more light-emitting elements operatively coupled to a substrate; a compound lens disposed to interact with light emitted by the one or more light-emitting elements, the compound lens including at least an inner lens element and an outer lens element, the inner lens element having a first index of refraction and the outer lens element having a second index of refraction, the first index of refraction being greater than the second index of refraction; the compound lens, the one or more light-emitting elements and the substrate defining an enclosed space between them; and an encapsulation material filling at least part of said space, the encapsulation material having a third index of refraction equal or greater than the first index of refraction.

### FIELD OF THE INVENTION

The invention pertains to light-emitting devices and in particular to the design of optical components of lighting device packages.

### BACKGROUND

Light-emitting diodes (LEDs) can be more effective if the LED package is adequately designed to effectively extract the light which is generated inside the LED package under operating conditions. From the perspective of a device designer, effective light extraction can be a matter of improving the chances that light from the LED dice can leave the LED package without having to undergo unnecessary reflections inside the LED package. A number of design features can influence the optical paths such as the orientation and the position of optical interfaces and the optical properties of the relevant components of the LED package such as the type of material on either side of an optical interface, for example. Moreover, the propagation of light inside the LED package can also depend on its wavelength, its intensity, the size and luminous efficacy of the LED dice, the drive current, the opacity of the optical elements of the LED package, the temperature conditions inside the LED package, the refractive indices of the ambient medium and the material of the LED package components as well as the temperature dependence of the refractive indices of the relevant materials, for example. State of the art LED packages have at least a LED die and an encapsulant lens. In some LED packages the lens and the encapsulant are separate or made of different materials. Consequently, an LED package can have a die-encapsulant optical interface, an encapsulant-lens optical interface and a lens-air optical interface.

Besides changing the direction of the propagation of the light emitted by an LED die, optical interfaces can reflect and transmit variable portions of light depending on the wavelength of the light, the incidence angle at an optical interface and the refractive indices of the two media on either side of an optical interface. Partial reflection and transmission at an optical interface of an LED package can cause a cascade of repeatedly reflected and transmitted rays. As a result, certain reflections may elongate the optical path which can increase the likelihood for undesired light absorption inside the LED package. Moreover, light can undergo total internal reflection (TIR) which can occur at certain incidence angles depending on the refractive index ratio. This effect can occur when light propagates within a medium which has a first refractive index and hits an optical interface with a thick enough layer of another medium which has a second refractive index which is smaller than the first refractive index. TIR substantially completely inhibits the transmission of light across and far beyond an optical interface. Furthermore, improper design of refractive elements can cause the LED to emit light with potentially impractical spatial light emission properties which can include brightness or colour irregularities in the light emission pattern due to monochromatic or chromatic aberration.

Even within the visible part of the spectrum the index of refraction of, for example, the LED dice can vary significantly. Most dice that are used today have refractive indices in the visible spectrum of higher than approximately 1.6. In addition, for example some blue and green LED dice have a refractive index of approximately 2.6 to 2.7. For example, if the ambient medium is air, which has a refractive index of approximately 1.0 and if the die refractive index is 1.6, the largest critical angle for TIR would be approximately 39 degrees to the optical interface normal. However, for other wavelengths the critical angle may be considerably smaller. Any light which hits the optical interface at larger angles will be totally internally reflected.

A known solution to reduce undesired reflections is to cover the LED dice with material with a refractive index which is between that of the dice and air or more generally to employ materials at optical interfaces which yield a low refractive index ratio. For example, one or more LED dice can be placed at the center of a hemispherical lens and the space between the dice and the lens can be filled with a transparent encapsulant. The materials for the encapsulant and the lens are chosen so that, among other requirements, their common refractive index, for example 1.5, progressively matches the refractive index of the dice, for example 2.65, to that of the ambient medium, which is 1.0. However, this design requires relatively large lens size when two or more LED dice are grouped together under one lens. For better color mixing it can be desirable, however, to have multiple LED dice inside the same package.

Some of these principles have been recognized in a number of publications. For example, U.S. Pat. No. 6,610,598 describes a surface-mounted device of light-emitting diodes (SMD LED) whose component typically has a plane on the surface. Through the calculation of Snell's Law, most of light fails to be emitted directly from the component because of the difference in the refractive index of the epoxy resin and the atmosphere (the refractive index of the light in the atmosphere is 1, the refractive index of the epoxy resin is around 1.5). A surface-mounted device of light-emitting diodes includes several small lens or diffraction lens on the planar surface of the SMD LED, wherein a lens that enlarges the critical angle can increase the direct light-emitting opportunity from the light-emitting chip, which in turn increases the brightness of the LED.

U.S. Pat. Nos. 6,590,235 and 6,204,523 provide an LED component, with light emission in the green-to-near UV wavelength range. The light-emitting semiconductor die is encapsulated with one or more silicone compounds, including a hard outer shell, an interior gel or resilient layer, or both. The silicone material is stable over temperature and humidity ranges, and over exposure to ambient UV radiation. As a consequence, the LED component has an advantageously long lifetime, in which it is free of “yellowing” attenuation which would reduce the green-to-near UV light output.

U.S. Pat. No. 6,639,360 provides a high power radiation emitter device and heat dissipating package for electronic components. The electronic component package includes a sealed chamber; a liquid or gel contained in the sealed chamber; at least one electronic component disposed in the sealed chamber in physical and thermal contact with the liquid or gel; and at least one electrical conductor electrically coupled to the electronic component and extending out of said sealed chamber. The electronic component(s) may include any one or combination of a radiation emitter, a thermal or optical sensor, a resistor, and a microprocessor or other semiconductor component.

U.S. Pat. No. 6,867,929 describes a light source device that is safe for human eyes and whose switching is performed at high speed. The light source device comprises one or more laser light sources for emitting a monochromatic or polychromatic light beam, a diffuser, which may be transmissive, reflective, or a mixture thereof, for diffusing the light beam received directly from the laser light source or via an optical focusing system, and an optical collimator, which collimates the diffused light bundle emitted from the diffuser.

U.S. Pat. No. 7,015,516 describes a light-emitting microelectronic package that includes a light-emitting diode having a first region of a first conductivity type, a second region of a second conductivity type, and a light-emitting p-n junction between the first and second regions. The light-emitting diode defines a lower contact surface and a mesa projecting upwardly from the lower contact surface. The first region of a first conductivity type is disposed in the mesa and defines a top surface of the mesa, and the second region of a second conductivity type defines the lower contact surface that substantially surrounds the mesa. The mesa includes at least one sidewall extending between the top surface of the mesa and the lower contact surface, the at least one sidewall having a roughened surface for optimizing light extraction from the package.

U.S. Pat. No. 7,023,022 describes a light-emitting package that includes a substantially transparent substrate having a first surface and a second surface including a lens. The package also includes a light-emitting diode (LED) adapted to emit light having a predetermined wavelength, the LED being secured over the first surface of the substantially transparent substrate. The second surface of the substrate defines a principal light emitting surface of the package. The lens at the second surface has a grating pattern that matches the predetermined wavelength of the light emitted from the LED for controlling the emission geometry of the light emitted by the package. The grating pattern has a radial configuration including a series of circles that are concentric.

U.S. Pat. No. 6,921,929 describes a light-emitting diode (LED) with amorphous fluoropolymer encapsulant and lens. The lens and encapsulant are made of an amorphous fluoropolymer for a LED or diode laser, such as an ultraviolet LED. A semiconductor diode die is formed by growing a diode on a substrate layer such as sapphire. The diode die is flipped so that it emits light through the face of the layer. An amorphous fluoropolymer encapsulant encapsulates the emitting face of the diode die, and may be shaped as a lens to form an integral encapsulant/lens. Or, a lens of amorphous fluoropolymer may be joined to the encapsulant. Additional joined or separate lenses may also be used. The encapsulant/lens is transmissive to UV light as well as infrared light. Encapsulating methods are also provided.

U.S. Pat. No. 7,026,657 describes a high radiance LED chip and a method for producing same. A light-emitting diode chip comprises a radiation-emitting active region and a window layer. To increase the luminous efficiency, the cross-sectional area of the radiation-emitting active region is smaller than the cross-sectional area of the window layer available for the decoupling of light. The invention is further directed to a method for fabricating a lens structure on the surface of a light-emitting component.

U.S. Pat. No. 6,903,380 describes a method and system for an LED package. The LED package may comprise a leadframe having an annular contact and a base contact. An LED die may be coupled to the annular and base contacts such that the P-type material portion is electrically connected to an annular contact and the N-type material portion is electrically connected to a base contact. Alternatively the N-type material portion may be electrically connected to the annular contact and the P-type material portion may be electrically connected to the base contact. A lens may be coupled to the leadframe, and an optical material may be located in a cavity defined by the lens, the base contact, and the annular contact. The optical material may be a gel, grease, a resilient material, a non-resilient material, a rigid material, a liquid material or a non-liquid material. The method and system may further comprise a mounting device, wherein the LED package is mechanically coupled to the mounting device in a socket, bayonet, or threaded fashion. The method and system may further comprise a strip comprising an array of annular contacts utilized to form an array of the LED packages and a carrier strip comprising receiving devices to receive the array of LED packages. A portion of the lens may either be coated with or comprise light excitable material or the optical material may comprise light excitable material, such that the system emits white light.

U.S. Pat. No. 6,480,389 describes a light emitting diode (LED) that includes a heat dissipation structure characterized by having a heat dissipating fluidic coolant filled in a hermetically sealed housing where at least one LED chip mounted on a metallic substrate is dwelled inside. The heat dissipation structure is configured with a metallic wall erected from the metallic substrate, which is used to hold a transparent cap of the sealed housing in correct position. Furthermore, the erected wall surrounds in proximity with the at least one LED chip, so that the joule heat generated therefrom can be quickly spread out, through the heat dissipating fluidic coolant, to the erected wall, and then diffused along the wall down to the metallic substrate which adjoins with a larger external heat sink for draining the heat, thus preventing the at least one LED from overheating. The other characteristic of the invention resides in that the transparent cap of the sealed housing is made of transparent materials, wherein a convex portion contacted with the heat dissipating fluidic coolant is formed on the inner surface of the transparent cap. Hence if there is any air bubble existing inside the housing due to insufficient filling, it will not dwell in the field of line-of-sight due to buoyancy. The possibility of scattering the LED light due to the existence of the bubbles therefore is avoided.

U.S. Pat. No. 5,077,587 describes a light-emitting diode with anti-reflection layer optimization. Improved light output from LEDs or the like are obtained by modifying the combined thickness dimensions of a transmissive diffusion mask layer and anti-reflection coating layer at the periphery of the window forming the light-emitting region.

United States Patent Publication No. 2006/0083000 describes a lens for a light emitting diode formed with a material having a refractive index of n, the lens including a base, a first curved circumferential surface extending from the base, a curved center-edge surface extending from the first curved circumferential surface, and a curved centermost surface extending from the curved center-edge surface. The base includes a groove for receiving a light emitting chip therein. In the lens, a distance from a center of the base to a point of the curved center-edge surface is always shorter than the radius of curvature for the point of the curved center-edge surface. The curved centermost surface has a concave shape with respect to the base. In addition, when an obtuse angle formed between a main axis of the lens and a tangent line of a point of the curved centermost surface is A1, and an acute angle formed between a straight line linking the center of the base to the point of the curved centermost surface and the main axis of the lens is A2, the lens satisfies the equation: A1+A2<90+1/sin(1/n).

United States Patent Publication No. 2005/0221519 describes semiconductor light emitting devices including a luminescent conversion element and methods for packaging the same. Methods of packaging the semiconductor light emitting device include dispensing a first quantity of encapsulant material into a cavity including the light emitting device. The first quantity of encapsulant material in the cavity is treated to form a hardened upper surface thereof having a selected shape. A luminescent conversion element is provided on the upper surface of the treated first quantity of encapsulant material. The luminescent conversion element includes a wavelength conversion material and has a thickness at a middle region of the cavity greater than proximate a sidewall of the cavity.

United States Patent Publication No. 2004/0079957 describes a power surface mount light-emitting die package. The die package includes a substrate, a reflector plate, and a lens. The substrate may be made from thermally conductive but electrically insulating material or from a material that is both thermally and electrically conductive. In embodiments wherein the substrate is made from an electrically conductive material, the substrate further includes an electrically insulating, thermally conductive material formed on the electrically conductive material. The substrate has traces for connecting to a light emitting diode (LED) at a mounting pad. The reflector plate is coupled to the substrate and substantially surrounds the mounting pad. The lens substantially covers the mounting pad. Heat generated by the LED during operation is drawn away from the LED by both the substrate (acting as a bottom heat sink) and the reflector plate (acting as a top heat sink). The reflector plate includes a reflective surface to direct light from the LED in a desired direction.

United States Patent Publication No. 2004/0041222 describes a power surface mount light emitting die package. The die package includes a substrate, a reflector plate, and a lens. The substrate is made from thermally conductive but electrically insulating material. The substrate has traces for connecting an external electrical power source to a light emitting diode (LED) at a mounting pad. The reflector plate is coupled to the substrate and substantially surrounds the mounting pad. The lens is free to move relative to the reflector plate and is capable of being raised or lowered by the encapsulant that wets and adheres to it and is placed at an optimal distance from the LED chip(s). The lens can be coated with an optical system comprising optical chemicals that affect the performance of the device. Heat generated by the LED during operation is drawn away from the LED by both the substrate (acting as a bottom heat sink) and the reflector plate (acting as a top heat sink). The reflector plate includes a reflective surface to direct light from the LED in a desired direction.

International Patent Publication No. 2006/021837 describes light-emitting diode systems including semiconductor diodes arranged in cooperation with electrical contacts, mounting provisions, and optical couplings; where the optical couplings include at least a Fresnel lens. A Fresnel lens is further coupled to additional optical elements such as a concave or ‘negative’ lens and still further to a reflector operating via principles of total internal reflection. Both the concave lens and the reflector are aspherical in preferred versions. A cover element of single piece plastic may be formed in a molding process whereby all three of these optical elements, i.e. the Fresnel lens, the negative lens and the reflector, are formed into the single plastic piece. Further, the plastic piece may be arranged to also accommodate auxiliary systems such as alignment indexing and fastening means as well as interlocking peripheral configurations.

International Patent Publication No. 2005/107420 describes a light-emitting apparatus including a source of light for emitting light; a down conversion material receiving the emitted light, and converting the emitted light into transmitted light and backward transmitted light; and an optic device configured to receive the backward transmitted light and transfer the backward transmitted light outside of the optic device. The source of light is a semiconductor light emitting diode, which may include alight emitting diode, a laser diode, or a resonant cavity light emitting diode. The down conversion material includes one of phosphor or other material for absorbing light in one spectral region and emitting light in another spectral region. The optic device, or lens, includes a light-transmissive material.

It is, however, not described how undesired internal reflections in lighting device packages can be reduced. Therefore there is a need for a new package design that overcomes some of the drawbacks of known designs.

This background information is provided to reveal information believed by the applicant to be of possible relevance to the invention. No admission is necessarily intended, nor should be construed, that any of the preceding information constitutes prior art against the invention.

### SUMMARY OF THE INVENTION

An object of the invention is to provide a lighting device package. In accordance with an aspect of the invention, there is provided a lighting device package comprising: one or more light-emitting elements operatively coupled to a substrate; a compound lens with a surface facing the one or more light-emitting elements, the compound lens including at least an inner lens element and an outer lens element, the inner lens element having a first index of refraction and the outer lens element having a second index of refraction, the first index of refraction being greater than the second index of refraction; the compound lens, the one or more light-emitting elements and the substrate defining an enclosed space between them; and an encapsulation material filling at least part of said space, the encapsulation material having a third index of refraction equal or greater than the first index of refraction.

In accordance with another aspect of the invention, there is provided a lighting device package comprising: one or more light-emitting elements operatively coupled to a substrate; a compound lens disposed to interact with light emitted by the one or more light-emitting elements, the compound lens including at least an inner lens element and an outer lens element, the inner lens element having a first index of refraction and the outer lens element having a second index of refraction, the first index of refraction being greater than the second index of refraction; the compound lens, the one or more light-emitting elements and the substrate defining an enclosed space between them; and an encapsulation material filling at least part of said space, the encapsulation material having a third index of refraction equal or greater than the first index of refraction.

### BRIEF DESCRIPTION OF THE FIGURES

FIG. 1 schematically illustrates a cross section of a lighting device package according to one embodiment of the invention.

FIG. 2 schematically illustrates a cross section of a lighting device package according to one embodiment of the invention.

### DETAILED DESCRIPTION OF THE INVENTION

### Definitions

The term “light-emitting element” (LEE) is used to define a device that emits radiation in a region or combination of regions of the electromagnetic spectrum for example, the visible region, infrared and/or ultraviolet region, when activated by applying a potential difference across it or passing a current through it, for example. Therefore a light-emitting element can have monochromatic, quasi-monochromatic, polychromatic or broadband spectral emission characteristics. Examples of light-emitting elements include semiconductor, organic, or polymer/polymeric light-emitting diodes, optically pumped phosphor coated light-emitting diodes, optically pumped nano-crystal light-emitting diodes or other similar devices as would be readily understood by a worker skilled in the art. Furthermore, the term light-emitting element is used to define the specific device that emits the radiation, for example a LED die.

As used herein, the term “about” refers to a ±10% variation from the nominal value. It is to be understood that such a variation is always included in any given value provided herein, whether or not it is specifically referred to.

Unless defined otherwise, all technical and scientific terms used herein have the same meaning as commonly understood in the art to which this invention belongs.

The invention provides a lighting device package which comprises one or more light-emitting elements operatively coupled to a substrate, and a compound lens disposed so to interact with light emitted by the one or more light-emitting elements, either directly, for example via a surface of the lens facing the one or more light-emitting elements, or indirectly, for example via one or more optical elements such as reflectors, diffusers, windows and the like.

In general, the compound lens can be formed from two or more lens elements, for example, each element can be an adequately thick lens layer with homogenous or non-homogenous thickness. The index of refraction of the outermost lens element of the compound lens is typically smaller than the index of refraction of the innermost lens element, i.e. the lens element closest to the LEEs. An encapsulation material fills an enclosed space located between the compound lens, the substrate and the one or more light-emitting elements. The encapsulation material is selected to have an index of refraction equal to or greater than the innermost lens element of the compound lens but smaller than the refractive index of the LEEs. Generally, the refractive indices decrease with distance of the respective components from the light-emitting elements in order to reduce the chances for (total) internal reflection of the light emitted by the LEEs within the light-emitting element package.

The invention can provide a lighting device package with reduced total internal reflection (TIR) compared to existing package design technologies. To facilitate small TIR, the lighting device package has a number of optical components made of materials which provide appropriate refractive indices. The optical components can be shaped and disposed to generally control the propagation of light inside the lighting device package and specifically to control the propagation of light emitted by the LEEs. The light-emitting element package can have one or more light-emitting elements, for example LED dice, which emit light under operating conditions. The light-emitting elements can be of different types and can emit light which can be nominally different in color or brightness. According to the invention, the configuration of the lighting device package determines how light that originates from the one or more light-emitting elements, is guided to the outside of the light-emitting element package.

Many light-emitting elements, for example LED dice are made of compound materials which can have high refractive indices. In one embodiment, a way to effectively guide the light from a light-emitting element to the ambient medium outside the light-emitting element package is to have the light consecutively propagate through a succession of materials with relatively small discontinuities between their indices of refraction. The closer the refractive indices are of adjacent materials at an optical interface, the smaller the solid angle within which total internal reflection can occur at that interface.

Light-propagation in lighting device package can also be affected by the type of light-emitting element, for example, by how an LED die is mechanically and electrically connected to a substrate. It is noted that light-emitting elements can be disposed and operatively connected using a number of different technologies, as is known in the art. For example, LEEs can be wire-bonded from the top of a substrate or surface mounted using a ball grid for a flip chip. Also, there can be one or more LED dice inside one light-emitting element, for example.

As mentioned above, TIR at each optical interface can be reduced, if the refractive index profile, for example, across the elements of a compound lens is characterised by small discontinuities or small gradients. The same considerations apply to the refractive index profile along the whole optical path from the one or more light-emitting elements to the ambient medium. The compound lens can have a number of elements, each element having a different refractive index, in which the refractive indices vary with distance from the LEEs in order to approach the refractive index of the ambient medium. For many applications, the ambient medium has a low refractive index close to 1.0, such as air has, for example. If the refractive index of the ambient medium is lower than the refractive index or indices of the LEEs, the elements of the compound lens can be designed to have refractive indices which decrease with increasing distance from the LEEs.

### Compound Lens

A compound lens is positioned relative to the substrate such that it can effectively optically interact with the light emitted by the one or more light-emitting elements. In one embodiment, the compound lens may be disposed to interact directly with the emitted light, namely via a surface of the lens facing the one or more light-emitting elements. In one embodiment of the present invention, the compound lens may be disposed to interact indirectly with the emitted light, namely via one or more reflectors, diffusers, windows and other such optical elements. In one embodiment of the present invention, the compound lens can be disposed to interact directly and indirectly with the emitted light.

The compound lens can be formed from two or more elements of materials with different refractive indices. The refractive index of the outermost element of the compound lens is typically smaller than the index of refraction of the one or more inner elements of material.

In one embodiment of the invention, the compound lens comprises one or a combination of solid, gel, liquid materials, encapsulation materials or the like.

In one embodiment of the invention, the exterior surface of the light-emitting element package has a hemispherical shape and can be defined by a compound lens. In comparison to a monolithic optical element of similar size and shape but of uniform composition or uniform optical properties, such a compound lens can offer better light extraction for a lighting device package with two or more light-emitting elements, or for large area light-emitting elements, for example LED dice. Consequently, the improved light extraction can allow lighting device packages with higher light-emitting element densities.

In one embodiment, hemispherical lenses can be used to manufacture lighting device packages which can emit light with Lambertian emission patterns. If it is desired that the lighting device package can emit light which has other than Lambertian emission patterns, the optical component of the compound lens can be adequately shaped or the thicknesses of, or relative distances between the optical components adequately dimensioned to provide optical interfaces different from the spherical shape.

In one embodiment of the invention, in order to achieve proximate normal incidence angles for light impinging at the inner surface of the inner element of the compound lens, the inner radius of the lens cavity may be about three or more times the size of the circular area inscribing the one or more light-emitting elements. In one embodiment of the invention, the hemispherical lens can be disposed relative to the substrate such that the light-emitting elements are positioned close to the spherical center of the internal hemispherical lens cavity.

Typical lens and encapsulation materials with suitable refractive indices can include PMMA, polycarbonate, nylon, COC, BK7 glass and silicone, for example, which typically absorb little visible light and only some ultra violet (UV) light. Some of these types of materials can provide resistance to discoloration under prolonged exposure to UV light and a range of suitable indices of refraction.

The compound lens can be manufactured in a number of different ways, for example, by shot moulding or other suitable manufacturing processes as would be known to a worker skilled in the art.

In one embodiment of the invention, two, three or more element lens can be manufactured using a multi-shot moulding process. For example, dual shot moulding can be used to fabricate a two element compound lens. Dual shot moulding can be used to manufacture components which provide additional mechanical interlocking elements. The interlocking elements can be formed during the moulding process and provide subsequent mechanical stability by locking the two components of the compound lens relative to each other. The type of interlocking can either be a destructively or non-destructively releasable bond depending on the shapes of the interlocking elements, the nature of the employed materials and the nature of the moulding process.

Generally, shot moulded components are formed in sequence of increasing shape complexity of their parts or sub-components. As is widely known, factors such as debonding or other undesired stress induced effects during manufacturing due to, for example, differing thermal expansion coefficients between mould materials may determine alternative manufacturing sequences. To provide individual parts with the desired refractive indices, a compound lens can be manufactured out of varying grades of the same type of materials such as certain silicones, or the like, for example.

As is known, the manufacturing of compound optical components requires the control of undesired types and amounts of inclusions inside the compound elements and at interfaces between the elements.

It is noted that other types of moulding processes may be used to manufacture separate parts which can be assembled into compound components or adhered to each other using, for example, optically clear adhesives. The adhesive can be chosen to provide a certain index of refraction. The refractive index of the adhesive may be between the refractive indices of the immediately adjacent parts, for example.

Typical compound lens materials that are adequate for lighting device packages can have refractive indices of approximately 1.40 or greater although materials with other refractive indices may be used.

### Encapsulation Material

An encapsulation material fills all or a portion of a space between the one or more light-emitting elements and the compound lens. According to the invention, the encapsulation material is selected to have an index of refraction equal to or greater than the index of refraction of the innermost element of the compound lens and smaller than the refractive index of the LEEs. Typically, encapsulation materials will have refractive indices of about 1.55.

Total internal reflection can be reduced when there are no undesired voids included at interfaces or within the encapsulation material, for example. In one embodiment, the encapsulation material may have an index of refraction similar to one of the LEEs. Encapsulation materials with adequate refractive indices slightly lower than the index of refraction of the LEEs can reduce the chances of light undergoing TIR at the optical interface between an LEE and the encapsulation material.

In one embodiment, the encapsulation material is made of, for example, fluid or highly elastic materials which can aid in the control of thermally induced stress at or near optical interfaces to mitigate undesired effects of differing thermal expansion coefficients and fluctuating thermal operating conditions. Fluid encapsulation material may additionally provide heat dispersion through convection.

In one embodiment of the invention, soft or fluid encapsulation materials or optical silicone can be sealed, for example, between an adjacent solid optical component such as compound lens and other elements such as the substrate. It is noted that encapsulation material may or may not be in direct thermal contact with one or more light-emitting elements.

Typical encapsulation materials include certain silicones and elastomers or clear gel with low ionic impurities such as Cl, K, Na, for example. A number of encapsulation materials are well known in the art and available under brand names such as Dow Corning™, Nye™ or Nusil™, for example.

### Substrate

The one or more light-emitting elements are operatively coupled to a substrate. The substrate can be a ceramic board, for example, AIN, a metal clad PC board, a LTCC on metal ceramic, an attach pad for insert moulded lead frame LEDs or the like as would be known in the art. The surface of the substrate facing the cavity, or certain areas of it, can be diffuse or specular reflective, for example. The reflective properties can result from, for example, aluminium or silver coatings and applied reflective films, for example.

### Evaluation of Index of Refraction

In one embodiment, it can be shown that the refractive indices n_{A}, n_{B}, n_{C} of a succession of materials A, B and C can be chosen according to n_{B}=\sqrt{n_{A}n_{C}}, to reduce the chances for TIR when light travels across two adjacent plan parallel optical interfaces AB and BC. The combination of refractive indices that reduces TIR may be governed by different formula for non-planar or non-parallel adjacent optical interfaces. For example, the refractive index obtained for medium B based on the index of refraction of A and C, for ideal plan parallel optical interfaces, may provide a reasonable estimate for the refractive index of medium B also for non-planar or non-parallel interfaces.

Other theoretical or experimental methods for determining the refractive index of encapsulation material based on the refractive indices of the surrounding materials from the compound lens and the LEE would be readily understood by a worker skilled in the art. It would also be understood that the refractive indices and other parameters of the components of the lighting device package may be selected to optimize one or more optical characteristics, which may include spectral and spatial radiation distributions, for example.

### Coatings

In one embodiment of the present invention, reflections inside lighting device packages can be further reduced by employing thin anti-reflective coatings on certain surfaces of certain components of the lighting device package. Such coatings can comprise multiple layers or films of material with differing optical characteristics. Each additional coating introduces another optical interface and can be tailored to improve the optical transmission characteristics at that interface and of the lighting device package overall. Typically coatings which can suppress undesired reflections are characterised by uniform thickness. The thickness may be smaller but of the order of the wavelength of the utility light. The respective films may have suitable refractive indices. For example, the exterior surface of the compound lens may be coated with a thin layer of material that has an index of refraction which is less than that of the material forming the outermost layer but higher than that of the ambient air. Coating materials typically require high transmissivity, resistance against discoloration and adequate adhesion to the coated component.

In one embodiment of the present invention the LEEs, for example the LED dice, can be coated with an anti-reflective, for example, conformal coating with an index of refraction between that of the medium surrounding the coating and that of the light-emitting elements. Similarly, the coating material has good transmissivity, particularly for visible light, resistance to discoloration, and good adhesion to the light-emitting element.

Anti-reflective coatings can comprise one or more layers of different materials or can be microscopically patterned as is widely known. Moreover, many coatings can be designed to provide optimal utility for light of a certain wavelength or polarization as well as for a certain incidence angle, for example. It is noted however that adequately designed multi-layer films can provide high transmissivity at a wide range of incidence angles.

The invention will now be described with reference to specific examples. It will be understood that the following examples are intended to describe embodiments of the invention and are not intended to limit the invention in any way.

### EXAMPLES

### Example 1

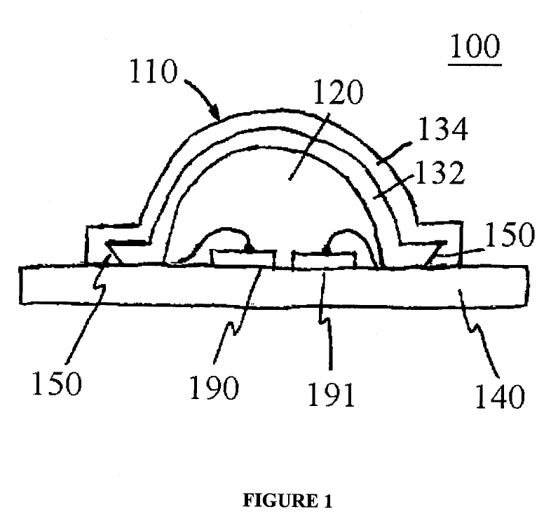

FIG. 1 schematically illustrates a cross section of a LED package 100 according to one embodiment of the invention. The LED package comprises a two layer lens 110, which defines a cavity 120 with a hemispherical inside and outside surface as well as a hemispherical interface between the two layers 132 and 134. It is understood that the inside and outside surfaces as well as the two layer interface can have other shapes and that the shape of the inside and outside surfaces can be different for different embodiments.

The LED dice 190 and 191 are disposed on a substrate 140 and are facing the cavity. It is noted that a different number of LED dice can be positioned inside the package. The cavity 120 can be filled with an encapsulation material. The substrate 140 can be a ceramic board, for example, AIN, FR4 or other printed circuit (PC) board, a metal clad PC board, a LTCC on metal ceramic, or an attach pad for insert moulded lead frame LEDs. The surface of substrate 140 facing the cavity, or a certain area of the substrate proximate dice 190 and 191, can be diffuse or specular reflective, for example. The reflective properties can result from, for example, aluminium or silver coatings.

The lens 110 comprises two layers of materials providing different indices of refraction. For example, the outer layer 134 of the lens can be made to have a refractive index smaller than the inner layer 132. The inner layer 132 forms the internal hemispherical lens cavity. The lens can have a wall thickness suitable for the overall size of the package, for example, between about 0.2 mm and about 1 mm thickness per layer. To help achieve proximate normal incidence angles for light impinging at the inner surface of the lens, the inner radius of the hemispherical lens cavity may be about three or more times the size of the circular area inscribing the LED dice and the LED dice should be disposed close to the spherical center of the internal hemispherical lens cavity. As defined above, it can be shown that the refractive indices n_{A}, n_{B}, n_{C} of a succession of materials A, B and C can be chosen according to n_{B}=\sqrt{n_{A}n_{C}}, to reduce the chances for TIR when light travels across two adjacent plan parallel optical interfaces AB and BC. For example, if the refractive index of lens layer 134 is about 1.40 and the one of the encapsulation material 120 is about 1.55, the material for lens layer 132 should provide a refractive index of about 1.47 (=\sqrt{1.40·1.55}).

The two layer lenses can be manufactured in a multi-shot moulding process. For example, dual shot moulding can be used to fabricate two layer compound lenses. Dual shot moulding can be used to manufacture components which provide additional interlocking elements. FIG. 1 illustrates an example of a two layer lens with interlocking elements 150. The interlocking elements can be formed during the moulding process and provide subsequent mechanical stability by locking the two components relative to each other. The type of interlocking can either be a destructively or non-destructively releasable bond depending on the shapes of the interlocking elements, the nature of the employed materials and the nature of the moulding process. Generally, shot moulded components are formed in sequence of increasing shape complexity of their parts or sub-components. For example, it may be easier to mould lens layer 132 and subsequently deposit lens layer 134 in a second mould shot.

### Example 2

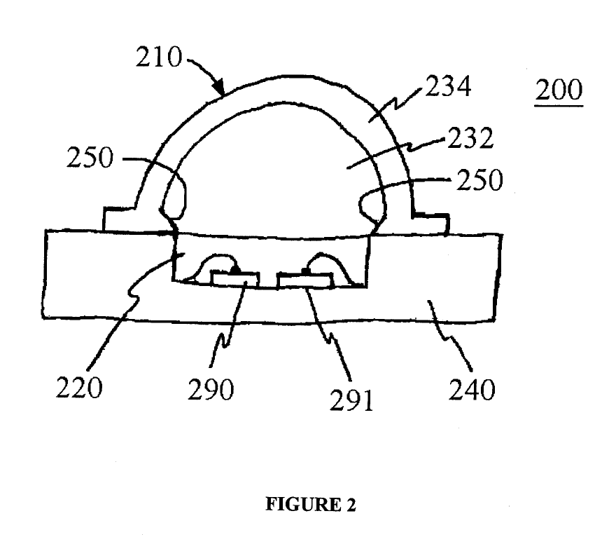

FIG. 2 schematically illustrates a cross section of another LED package 200 according to another embodiment of the invention. This embodiment is similar to the one illustrated in FIG. 1 but comprises a compound lens 210 with a solid hemi-spherical interior lens element 232 which is covered by an outer lens layer 234. The outer lens layer 234 is attached to the solid hemi-spherical interior lens element 232 by interlocking elements 250.

In order to accommodate the LED dice 290 and 291 under the compound lens, these are disposed in a recess 220 in the substrate 240. The recess defines a cavity between the compound lens 210 and the substrate 240. The surface of the solid hemi-spherical lens element proximate to the LED dice can be essentially flat but can be textured or structured to improve light penetration from the cavity into the lens element. The cavity can be filled with an encapsulant with a suitable index of refraction.

In this embodiment, different considerations for refractive indices apply in comparison to the foregoing embodiment because of the different shape and geometry of the encapsulation material-lens optical interface. For example, the encapsulation material can have a refractive index of about 1.55, and the solid hemi-spherical interior lens element can have a refractive index of about 1.55. It is noted that depending on the emission characteristics of the LED die, improper choice of refractive indices of the solid hemi-spherical interior lens element and the encapsulation material of LED package 200 can result in undesired TIR. The overall light extraction efficiency of LED package 200 can be improved if the encapsulation material and the solid hemi-spherical interior lens element provide equal refractive indices, for example.

In one embodiment, the formation of desired radiation patterns, for example a batwing emission pattern, can be facilitated by disposing the one or more LED dice proximate to suitably shaped reflector elements (not illustrated). For example, the recess in FIG. 2 or the surface of the substrate facing the cavity in FIG. 1 can be coated with a highly reflective material to form a reflector element or an additional reflective element may be disposed in the cavity. A number of the foregoing components or other additional components may be employed in the LED package that can act as reflector elements. Reflector elements can be formed out of suitably coated or shaped components, for example, cavities in a metal heat spreader, in a substrate or in a lead frame. Alternatively, reflector elements can also be achieved using materials which provide indices of refraction in such sequences that can cause total internal reflection of large amounts of light.

It is apparent that the foregoing embodiments of the invention are exemplary and can be varied in many ways. Such present or future variations are not to be regarded as a departure from the spirit and scope of the invention, and all such modifications as would be obvious to one skilled in the art are intended to be included within the scope of the following claims.

We claim:

1. A lighting device package comprising:
a) one or more light-emitting elements operatively coupled to a substrate;
b) a compound lens with a surface facing the one or more light-emitting elements, the compound lens including at least an inner lens element and an outer lens element, the inner lens element having a first index of refraction and the outer lens element having a second index of refraction, the first index of refraction being greater than the second index of refraction; the compound lens, the one or more light-emitting elements and the substrate defining an enclosed space between them; and
c) an encapsulation material filling at least part of said space, the encapsulation material having a third index of refraction equal or greater than the first index of refraction.

2. The lighting device package according to claim 1, wherein the light-emitting elements have an index of refraction larger than the third index of refraction.

3. The lighting device package according to claim 1, wherein the inner lens element comprises interlocking elements for engaging the outer lens element.

4. The lighting device package according to claim 1, wherein the outer lens element comprises interlocking elements for engaging the inner lens element.

5. The lighting device package according to claim 1, wherein the substrate has a surface on the side of the light-emitting elements which is reflective at least proximate to the light-emitting elements.

6. The lighting device package according to claim 5, wherein the substrate has a reflective coating disposed on the side of the light-emitting elements at least proximate to the light-emitting elements.

7. The lighting device package according to claim 1, wherein the compound lens is at least partially spherically shaped.

8. The lighting device package according to claim 1, wherein the compound lens comprises a plurality of elements that have refractive indices which decrease with increasing distance from the light-emitting elements.

9. The lighting device package according to claim 8, wherein the plurality of elements have discontinuously decreasing refractive indices.

10. The lighting device package according to claim 8, wherein the plurality of elements have continuously decreasing refractive indices.

11. The lighting device package according to claim 1, wherein the compound lens is manufactured by shot moulding.

12. The lighting device package according to claim 1, wherein the compound lens is manufactured by multi-shot moulding.

13. The lighting device package according to claim 1, wherein a surface of the inner lens element is in plane with a side of the substrate with the light-emitting elements.

14. The lighting device package according to claim 1, wherein a surface of the outer lens element is in plane with a side of the substrate with the light-emitting elements.

15. The lighting device package according to claim 1, wherein a surface of the compound lens is in plane with a side of the substrate with the light-emitting elements.

16. The lighting device package according to claim 1, wherein the light-emitting elements are disposed in a recess of the substrate.

17. The lighting device package according to claim 1, wherein an interface between the encapsulation material and the inner lens element is substantially flat and wherein the third index of refraction is about equal to the first index of refraction.

18. The lighting device package according to claim 1, wherein the third index of refraction is greater than the first index of refraction.

19. A lighting device package comprising:
a) one or more light-emitting elements operatively coupled to a substrate;
b) a compound lens disposed to interact with light emitted by the one or more light-emitting elements, the compound lens including at least an inner lens element and an outer lens element, the inner lens element having a first index of refraction and the outer lens element having a second index of refraction, the first index of refraction being greater than the second index of refraction; the compound lens, the one or more light-emitting elements and the substrate defining an enclosed space therebetween; and
c) an encapsulation material filling at least part of said space, the encapsulation material having a third index of refraction equal or greater than the first index of refraction.

20. The lighting device package according to claim 19, the compound lens comprising a surface facing the one or more light-emitting elements thereby providing for direct interaction between the compound lens and light emitted by the light-emitting elements.

21. The lighting device package according to claim 19, wherein the compound lens is disposed to interact indirectly with light emitted by the light-emitting elements via one or more optical elements.
